(19) United States
(12) Patent Application Publication
(10) Pub. No.: US 2006/0284242 A1
(43) Pub. Date: Dec. 21, 2006

(54) Non-volatile memory device having floating gate and methods forming the same

(76) Inventor: Sang-Youn Jo, Suwon-si (KR)

Correspondence Address: F. CHAU & ASSOCIATES, LLC, 130 WOODBURY ROAD, WOODBURY, NY, 11797, US

(21) Appl. No.: 11/449,036

(22) Filed: Jun. 7, 2006

(30) Foreign Application Priority Data
Jun. 7, 2005 (KR) 2005/0048517

(51) Int. Cl. H01L 29/788; H01L 21/336

(52) U.S. Cl. 257/316; 438/263; 438/266; 438/593; 257/321

(57) ABSTRACT

A non-volatile memory device includes a device isolation layer disposed on a semiconductor substrate to define an active region, a floating gate disposed on the active region including a flat portion and a wall portion extending upwardly from an edge of the flat portion, a tunnel insulator interposed between the floating gate and the active region and a control gate electrode crossing over the active region and covering an inner side of the floating gate and at least a part of an outer side of the floating gate. The non-volatile memory device further includes a blocking insulator interposed between the control gate electrode and the floating gate.

### CROSS-REFERENCE TO RELATED APPLICATIONS

This application claims priority from Korean Patent Application No. 10-2005-0048517, filed Jun. 7, 2005, the disclosure of which is hereby incorporated by reference herein in its entirety.

### BACKGROUND

1. Technical Field

The present disclosure relates to a non-volatile memory device and methods of forming the same. More specifically, the present disclosure is directed to a non-volatile memory device having a floating gate and a method of forming the same.

2. Discussion of Related Art

Non-volatile memory devices may retain their stored data even when their power supplies are interrupted. An example of a non-volatile memory device is the mask ROM non-volatile memory device. However, there are certain difficulties associated with mask ROM non-volatile memory devices in connection with their ability to erase and program data which has already been written. Accordingly, non-volatile memory devices which are sufficiently capable of programming and erasing data have subsequently been developed.

For example, programmable and erasable non-volatile memory devices include flash memory devices, ferroelectric memory devices, phase-change memory devices, and magnetic memory devices. A flash memory device may store data using a threshold voltage fluctuated depending on whether there are charges in a floating gate, and a ferroelectric memory device may store data using a polarization hysterisis characteristic. Further, a phase-change memory device may store data using a phase-change material in which a resistance value is variable with the supply of external heat. Moreover, a magnetic memory device may store data using a magnetic tunnel junction (MTJ) in which a resistance value is variable with the changing of a polarization orientation by an external magnetic field.

Flash memory devices are used in a variety of applications. In a flash memory device, data is typically programmed by injecting charges into a floating gate and erased by ejecting charges from the floating gate. In these flash memory devices, charges may tunnel an insulation layer interposed between a floating gate and a semiconductor substrate by means of hot carrier injection or FN tunneling. For instance, when operating a conventional flash memory cell, an operating voltage is typically applied to a control gate electrode over a floating gate. A voltage is then induced by the operating voltage, thereby injecting charges into the floating gate or ejecting charges from the floating gate.

However, with the trend toward higher integration and lower power consumption for semiconductor devices, there has been an increased focus on the coupling ratio of a flash memory cell. For example, as the coupling ratio increases, the ratio of a voltage induced to a floating gate to an operating voltage applied to a control gate electrode also increases. In addition, as the operating voltage is inversely proportional to the coupling ratio, increasing the coupling ratio may result in the operating voltage dropping as well. Moreover, when the operating voltage drops, the power consumption of a flash memory cell may also be reduced. Accordingly, there have been several approaches for increasing the coupling ratio of a flash memory cell. One of these approaches is to increase the capacitance between a control gate electrode and a floating gate. However, there may be difficulties associated with the above-mentioned conventional method when seeking to form a highly integrated semiconductor device because within a limited area, it may be difficult to increase the capacitance between a control gate electrode and a floating gate.

Thus, there is a need for a highly integrated non-volatile memory device having a low power consumption.

### SUMMARY OF THE INVENTION

Exemplary embodiments of the present invention are directed to a non-volatile memory device and a method of forming the same. According to an exemplary embodiment of the present invention, a non-volatile memory device is provided. The non-volatile memory device includes a device isolation layer disposed on a semiconductor substrate to define an active region, a floating gate disposed on the active region and including a substantially flat portion and a wall portion extending upwardly from the edge of the substantially flat portion, a tunnel insulator interposed between the floating gate and the active region and a control gate electrode crossing over the active region and covering an inner side of the floating gate and at least a part of an outer side of the floating gate. The non-volatile memory device further includes a blocking insulator interposed between the control gate electrode and the floating gate.

According to an exemplary embodiment of the present invention a method of forming a non-volatile memory device is provided. The method includes forming a device isolation layer on a semiconductor substrate to define an active region, forming a gate insulator on a predetermined region of the active region, forming a floating gate on the gate insulator. The floating gate includes a substantially flat portion and a wall portion extending upwardly from the edge of the substantially flat portion, and wherein inner and outer sides of the floating gate are exposed. The method further includes forming a blocking insulator on substantially an entire surface of a semiconductor substrate including the floating gate and forming a control gate electrode on the blocking insulator to cross over the active region. The control gate electrode is formed to cover the inner side of the floating gate and at least a part of the outer side of the floating gate.

### BRIEF DESCRIPTION OF THE DRAWINGS

FIG. 1A is a top plan view of a non-volatile memory device according to an exemplary embodiment of the present invention.

FIG. 1B and FIG. 1C are cross-sectional views taken along lines I-I′ and II-II′ of FIG. 1A, respectively.

FIG. 2 is a cross-sectional view of a modified version of the non-volatile memory device according to an exemplary embodiment of the present invention.

FIG. 3A through FIG. 8A are top plan views explaining a method of forming a non-volatile memory device according to an exemplary embodiment of the present invention.

FIG. 3B through FIG. 8B are cross-sectional views taken along lines III-III′ of FIG. 3A through FIG. 8A, respectively.

FIG. 3C through FIG. 8C are cross-sectional views taken along lines IV-IV′ of FIG. 3A through FIG. 8A, respectively.

### DETAILED DESCRIPTION OF EXEMPLARY EMBODIMENTS

The Exemplary Embodiments of the present invention will be described more fully hereinafter with reference to the accompanying drawings. This invention, however, may be embodied in many different forms and should not be construed as limited to the embodiments set forth herein.

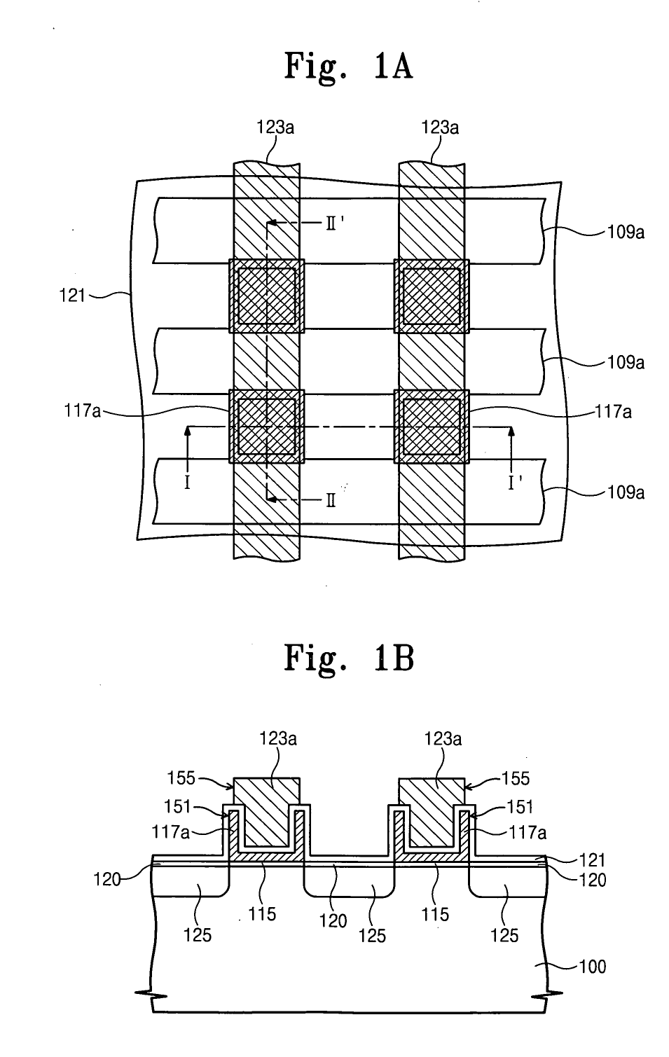

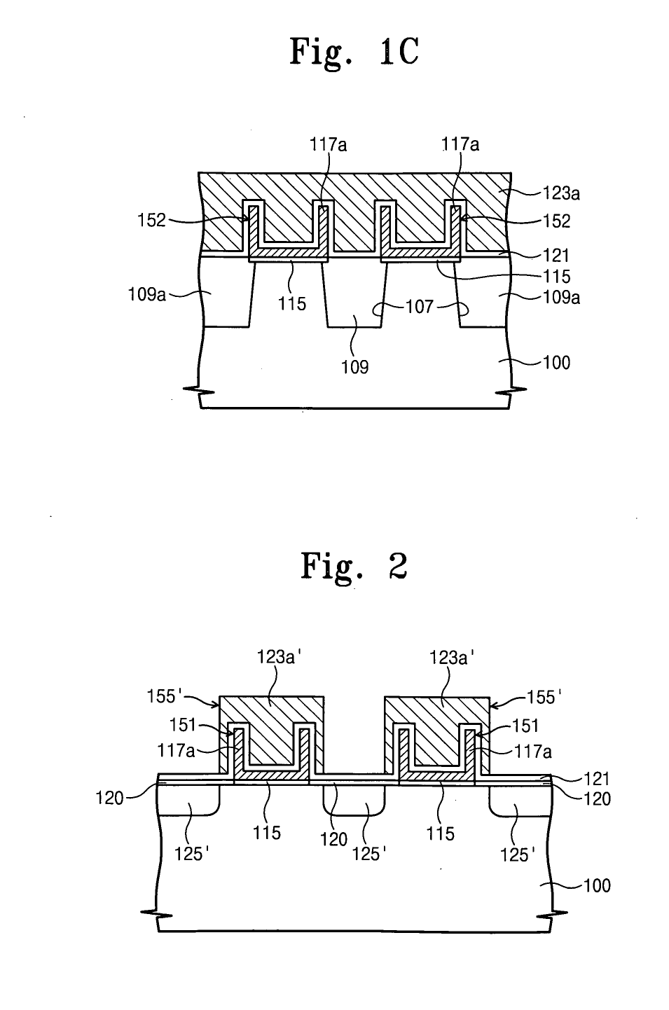

FIG. 1A is a top plan view of a non-volatile memory device according to an exemplary embodiment of the present invention. FIG. 1B and FIG. 1C are cross-sectional views taken along lines I-I′ and II-II′ of FIG. 1A, respectively.

Referring to FIG. 1A, FIG. 1B, and FIG. 1C, device isolation layers 109a are disposed on predetermined regions of a semiconductor substrate 1 to define active regions. The device isolation layers 109a may be linear when viewed from the top. Namely, the device isolation layers 109a are linearly. arranged on the semiconductor substrate 1 to run parallel with one another. Accordingly, the active regions may also be linear when viewed from the top. The device isolation layers 109a fill trenches formed in predetermined regions of the semiconductor substrate 1. Each of the device isolation layers 109a may be made of, for example, silicon oxide, or high-density plasma (HDP) silicon oxide having sufficient gap-fill properties.

A floating gate 117a is disposed on a predetermined region of the active region. A tunnel insulator 115 is interposed between the floating gate 117a and the active region. The floating gate 117a may be in the form of, for example, a channel or trough shape t. The floating gate 117a includes a flat portion and a wall portion extending upwardly from the edge of the flat portion. The tunnel insulator 115 is interposed between the flat portion of the floating gate 117a and the active region.

The floating gate 117a includes an inner side and an outer side. The inner side of the floating gate 117a corresponds to an inner side of the wall portion, which is in contact with an empty region surrounded by the wall portion. The outer side of the floating gate 117a corresponds to the outer side of the wall portion, which is opposed to the inner side of the wall portion. The outer side of the floating gate 117a includes a first outer side 151 adjacent to the active region and a second outer side 152 adjacent to the device isolation layer 109a.

The first and second outer sides 151 and 152 are exposed. A top surface of the device isolation layer 109a is lower than that of the wall portion of the floating gate 117a, exposing the second outer side 152 of the floating gate 117a. The top surface of the device isolation layer 109a may be formed substantially level with a bottom surface of the flat portion of the floating gate 117a. Alternatively, a central portion of the top surface of the device isolation layer 109a may be formed lower than the bottom surface of the flat portion of the floating gate 117a, thereby substantially or fully exposing the second outer side 152 of the floating gate 117a. The device isolation layer 109a may cover a side of the gate insulator 115. Moreover, the inner side and the top surface of the flat portion of the floating gate 117a are also exposed.

A blocking insulator 121 is disposed to cover a surface of the floating gate 117a. At this point, the blocking insulator 121 covers the inner side and the first and second outer sides 151 and 152 of the exposed floating gate 117a and a top surface of the flat portion. The blocking insulator 121 may extend to cover an entire surface of the semiconductor substrate 100.

A control gate electrode 123a is disposed on the blocking insulator 121 to cross over the active region. The control gate electrode 123a covers the inner side of the floating gate 117a. For example, the control gate electrode 123a covers an entire inner side of the floating gate 117a, which is disposed opposite to the first and second outer sides 151 and 152 of the floating gate 117a. Further, the control gate electrode 123a covers at least one portion of the outer side of the floating gate 117a. Moreover, the control gate electrode 123a covers the second outer side 152 of the floating gate 117a. In addition, the control gate electrode 123a covers the top surface of the flat portion of the floating gate 117a. The control gate electrode 123a may fill the empty region surrounded by the wall portion of the floating gate 117a with the blocking insulator 121 interposed therebetween. Opposite sides 155 of the control gate electrode 123a may be disposed on the blocking insulator 121 which is disposed on the top surface of the wall portion of the floating gate 117a.

The floating gate 117a may be in the form of, for example, a channel or trough shape. The control gate electrode 123a covers an entire inner side and a partial outer side of the floating gate 117a as well as the top surface of the flat portion of the floating gate 117a. Hence, an overlap area of the floating gate 117a and the control gate electrode 123a is maximized within a limited plan area to increase the capacitance therebetween. Thus, the coupling ratio of a non-volatile memory device is raised to drop the operating voltage (e.g., program or erase voltage) thereof. As a result, a highly integrated non-volatile memory device having lower power consumption may be obtained.

The floating gate 117a has a pair of the second outer sides 152 facing each other. The pair of the second outer sides 152 are contiguous to the device isolation layer 109a disposed at opposite sides adjacent to the active region, respectively. The active region has a second width that is parallel with a first width between the pair of the outer sides 152. The first width is greater than the second width. Accordingly, the surface area of the floating gate 117a increases more and thus the overlap area of the control gate electrode 123a and the floating gate 117a also increases. As a result, the coupling ratio is raised to enable the operating voltage of the non-volatile memory device to drop.

A capping pattern may be stacked on the control gate electrode 123a.

An impurity-doped layer 125 is disposed in the active region formed at opposite sides adjacent to the control gate electrode 123a. Opposite sides of the control gate electrode 123a are disposed on the wall portion of the floating gate 117a, allowing the impurity-doped layer 125 to be aligned with the first outer side 151 of the floating gate 117a.

The blocking insulator 121 may extend to cover a top surface of the impurity-doped layer 125. In this case, a buffer insulator 120 may be interposed between the blocking insulator 121 and the active region in which the impurity-doped layer 125 is formed. The buffer insulator 120 may exert a buffer function when a stress is generated between the blocking insulator 121 and the active region. In addition, the buffer insulator 120 may exert a function to prevent a reaction between the blocking insulator 121 and the active region. In other exemplary embodiments of the present invention, the buffer insulator 120 may be omitted.

The floating gate 117a may be made of, for example, undoped polysilicon or doped polysilicon. The tunnel insulator 115 may be made of, for example silicon oxide or thermal oxide. The blocking insulator 121 includes an insulating material having a higher dielectric constant than the tunnel insulator 115. Thus, the blocking insulator 121 may include, for example, an oxide-nitride-oxide (ONO) layer or an insulative metal oxide layer (e.g., hafnium oxide or aluminum oxide) having a high dielectric constant. As the blocking insulator 121 includes an insulating material having a high dielectric constant, the capacitance between the control gate electrode 123a and the floating gate 117a increases and thus the coupling ratio may be raised as well. The control gate electrode 123a includes a conductive material. The control gate electrode 123a may be made of at least one material selected from the group consisting of, for example, doped polysilicon, conductive metal nitride (e.g., titanium nitride or tantalum nitride), metal (e.g., tungsten or molybdenum), metal silicide (e.g., tungsten silicide or cobalt silicide), and combinations thereof. The buffer insulator 120 may be made of, for example, silicon oxide.

The control gate electrode 123a may have another shape, which will now be described with reference to FIG. 2. In FIG. 2 and FIG. 1, the same components are designated by the same numerals.

As illustrated in FIG. 2, floating gate 117a may be in the form of, for example, a channel or trough shape, and includes a flat portion and a wall portion extending upwardly from the edge of the flat portion. The floating gate 117a has an inner side, a first outer side adjacent to an active region, and a second outer side adjacent to a device isolation layer.

A control gate electrode 123a′ crosses over the active region and covers the floating gate 117a. A blocking insulator 121 is interposed between the control gate electrode 123a′ and the floating gate 117a. Similar to the exemplary embodiment depicted in FIGS. 1A-1C, the control gate electrode 123a′ covers the inner side of the floating gate 117a, the second outer side of the floating gate 117a, and a top surface of the flat portion of the floating gate 117a. In addition, the control gate electrode 123a′ extends to cover the first outer side of the floating gate 117a. Thus, opposite sides 155′ of the control gate electrode 123a′ are disposed on the active region beside the floating gate 117a. At this point, the blocking insulator 121 extends to be interposed between the active region and a portion covering the first outer side 151 of the control gate electrode 123a′. A buffer insulator 120 may be interposed between the blocking insulator 121 and the active region.

An impurity-doped layer 125′ is disposed in the active region and formed at opposite sides adjacent to the control gate electrode 123a′. The control gate electrode 123a′ covers the first outer side 151 of the floating gate 117a, enabling the impurity-doped layer 125a′ to be aligned with the opposite sides 155′ of the control gate electrode 123a′.

The control gate electrode 123a′ covers the inner side and the second outer side of the floating gate 117a and the top surface of the flat portion of the floating gate 117a as well as the first outer side 151 of the floating gate 117a. Accordingly, an overlap area of the control gate electrode 123a′ and the floating gate 117a increases and thus the coupling ratio of the non-volatile memory device may be raised. As a result, with the exemplary embodiments of the present invention, a non-volatile memory device having a coupling ratio raised within a limited area may be obtained.

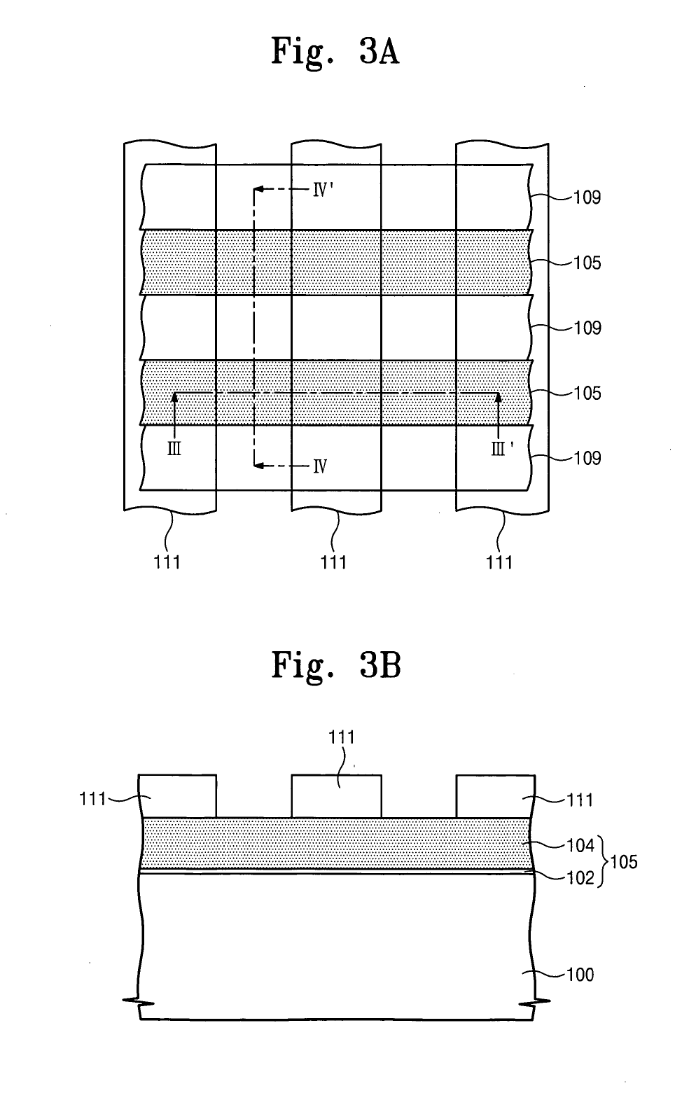

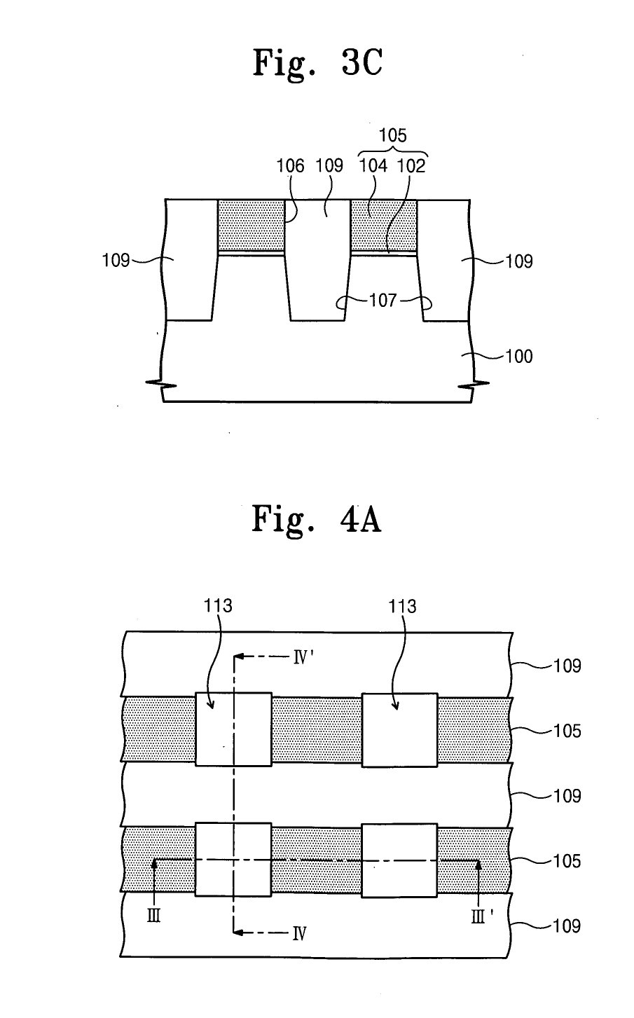

FIG. 3A through FIG. 8A are top plan views explaining a method of forming a non-volatile memory device according to an exemplary embodiment of the present invention. FIG. 3B through FIG. 8B are cross-sectional views taken along lines III-III′ of FIG. 3A through FIG. 8A, respectively. FIG. 3C through FIG. 8C are cross-sectional views taken along lines IV-IV′ of FIG. 3A through FIG. 8A, respectively.

Referring to FIG. 3A, FIG. 3B, and FIG. 3C, a hard mask layer is formed on a semiconductor substrate 100. The hard mask layer is patterned to form a hard mask pattern 105 and an opening 106 exposing a predetermined region of the semiconductor substrate 100. The semiconductor substrate 100 covered with the hard mask pattern 105 corresponds to an active region. The hard mask pattern 105 may be linear, e.g., hard mask patterns 105 may be linearly formed on the semiconductor substrate 100 to run parallel with one another. The semiconductor substrate 100 between the hard mask patterns 105 is exposed. The opening 106 between the hard mask patterns 105 is defined. The opening 106 may be groove shaped.

The hard mask pattern 105 includes a material having an etch selectivity with respect to the semiconductor substrate 100. For example, the hard mask pattern 105 may include a first layer 102 and a second layer 104 that are stacked in the order named. The second layer 104 is made of a material having an etch selectivity with respect to the semiconductor substrate 100, and the first layer 102 is made of a material having an etch selectivity with respect to the second layer 104. The first layer 102 may play a role in buffering a stress between the second layer 104 and the semiconductor substrate 100. In this regard, the first layer 102 may be made of, for example, silicon oxide and the second layer 104 may be made of, for example, silicon nitride.

Using the hard mask pattern 105 as an etch mask, the exposed semiconductor substrate 100 is etched to form a trench 107. The trench 107 defines an active region. An insulation layer is formed on an entire surface of the semiconductor substrate 100 to fill the trench 107. The insulation layer is made of a material having sufficient gap-fill properties and an etch selectivity with respect to the hard mask pattern 105. For this reason, the insulation layer may be made of, for example, silicon oxide or high-density plasma (HDP) silicon oxide.

The top surface of the hard mask pattern 105 is planarized, forming a device isolation layer 109 to fill the trench 107. The insulation layer fills the trench 107 and the opening 106. Accordingly, the device isolation layer 109 fills the trench 107 and the opening 106.

Before the insulation layer is formed, a thermal oxidation process may be performed to cure etch damage of an inner side and a bottom surface of the trench 107. Further, after the thermal oxidation process is performed and before the insulation layer is formed, a liner may be formed. The liner may be made of, for example, silicon nitride.

A mask pattern 111 is formed on a semiconductor substrate 100 including the device isolation layer 109. As the mask pattern covers only a portion of the hard mask pattern 105, the other portions of the hard mask pattern 105 are left exposed. The mask pattern 111 is made of a material having an etch selectivity with respect to the hard mask pattern 105. For this reason, the mask pattern 111 may be made of, for example, a photoresist pattern.

The mask pattern 111 is linearly formed to cross over the hard mask pattern 105 and the device isolation layer 109. For example, a plurality of mask patterns 111 are formed on the semiconductor substrate to run parallel with one another. Thus, the hard mask pattern 105 and the device isolation layer 109 exposed between the mask patterns 111 are exposed. Alternatively, the mask pattern 111 may extend to cover the device isolation layer 109 formed at opposite sides adjacent to the exposed hard mask pattern 105. This exemplary embodiment will be described with regard to a situation where the mask pattern 111 is linearly formed to expose the hard mask pattern 105 and the device isolation layer 109 between the mask patterns 111.

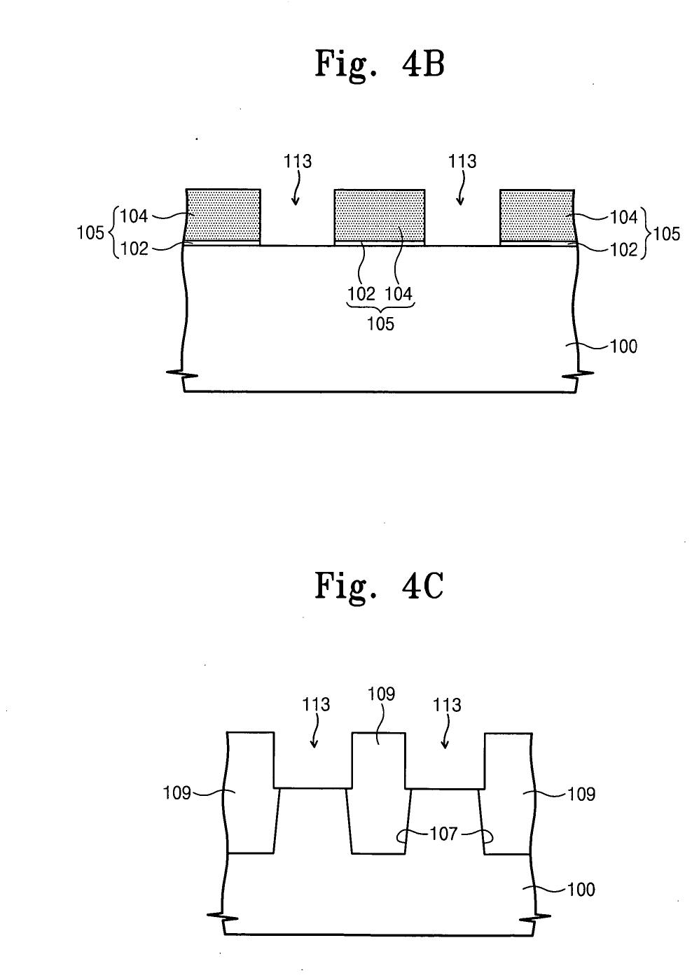

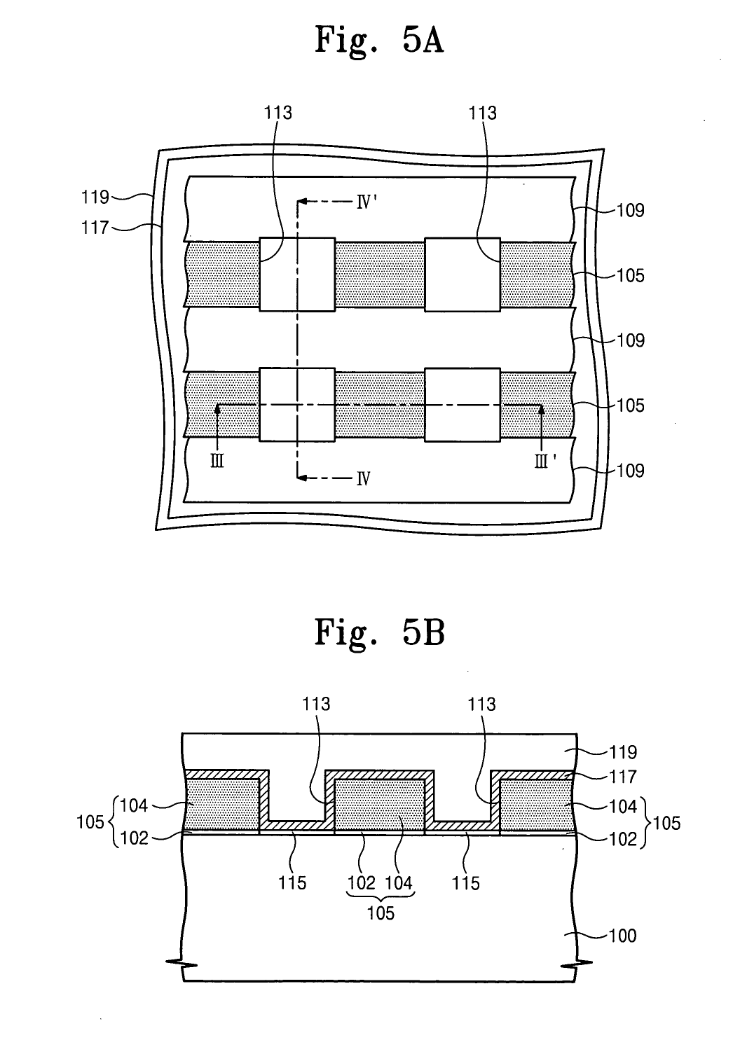

Referring to FIG. 4A, FIG. 4B, and FIG. 4C, the exposed hard mask pattern 105 is etched using the mask pattern 111 as an etch mask, forming a gate hole 113 to expose a predetermined region of the active region. The device isolation layer 109 has an etch selectivity with respect to the hard mask pattern 105, selectively etching the exposed hard mask pattern 105. The gate hole 113 is surrounded by the device isolation layer 109 and the patterned hard mask pattern 105. In other words, an inner side of the gate hole 113 includes an upper portion of the device isolation layer 109 (the upper portion protruding upwardly from a surface of the semiconductor substrate 100) and the patterned hard mask pattern 105.

The formation of the gate hole 113 may be done by successively etching the hard mask pattern 105 and the first and second layers 102 and 104 using the mask pattern 111 as an etch mask.

Alternatively, the gate hole 113 may be formed by another methodwhich will now be described in detail. For example, the second layer 104 of the hard mask pattern 105 is anisotropically etched using the mask pattern 111 as an etch mask, exposing the first layer 102. The mask pattern 111 is then removed. The exposed first layer 102 is removed by means of an isotropic wet etch, forming the gate hole 113 to expose the active region. As the removal of the first layer 102 is performed by means of the isotropic wet etch, the surface of the exposed active region may be protected from damage arising from the anisotropic etch. When the isotropic wet etch is conducted, the device isolation layer 109 is also recessed. Both the device isolation layer 10 and the first layer 102 are made of silicon oxide. For this reason, when the first layer 102 is removed by means of the wet etch, the device isolation layer 109 may be recessed isotropically. Thus, the gate hole 113 may have a greater width than the active region.

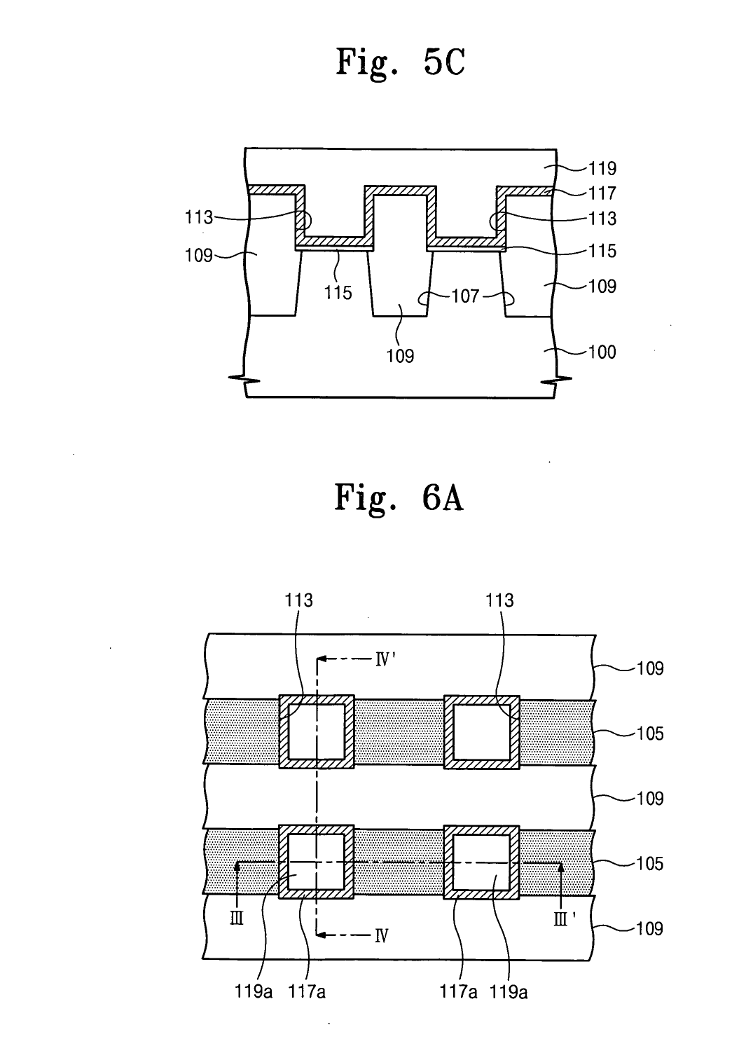

Referring to FIG. 5A, FIG. 5B, and FIG. 5C, a tunnel insulator 115 is formed on a semiconductor substrate 100 including the gate hole 113. The tunnel insulator 115 is disposed on the active region exposed by the gate hole 113. The tunnel insulator 115 may be made of, for example,silicon oxide or thermal oxide.

A gate layer 117 is formed on an entire surface of a semiconductor substrate 100 including the tunnel insulator 115. The gate layer 117 is disposed along a top surface of the patterned hard mask pattern 105 and an inner side and a bottom surface (for example, a top surface of the gate insulator 115) of the gate hole 113. The gate layer 117 may be made of, for example, undoped polysilicon or doped polysilicon. The patterned hard mask pattern 105 has an etch selectivity with respect to the gate layer 117.

A sacrificial layer 119 is formed on the gate layer 117. The sacrificial layer 119 is made of a material having an etch selectivity with respect to the gate layer 117. For this reason, the sacrificial layer 119 may be made of, for example, silicon oxide, silicon oxynitride or silicon nitride. In addition, the gate layer 117 may be made of a material having an etch selectivity with respect to the gate layer 117 and the device isolation layer 109. In a case where the sacrificial layer 119 has an etch selectivity with respect to the gate layer 117 and the device isolation layer 109, the sacrificial layer 119 may be made of silicon oxynitride or silicon nitride. The sacrificial layer 119 may fill the gate hole 113.

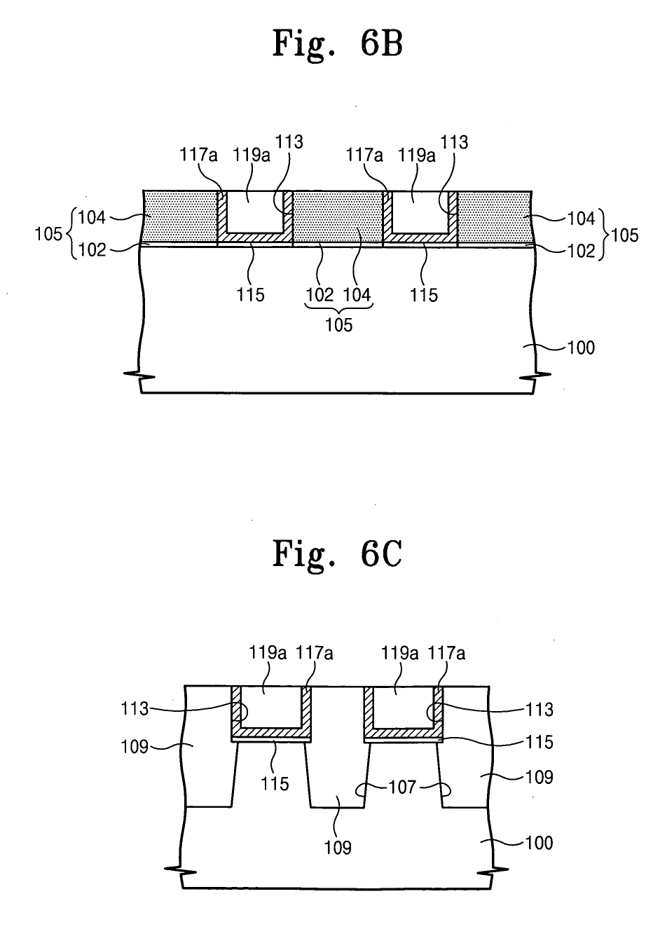

Referring to FIG. 6A, FIG. 6B, and FIG. 6C, the sacrificial layer 119 and the gate layer 117 are planarized down to a top surface of the patterned hard mask pattern 105, forming a floating gate 117a and a sacrificial pattern 119a which are sequentially stacked in the gate hole 113. The floating gate 117a may be in the form of for example, a channel or trough shape. The floating gate 117a includes a flat portion and a wall portion extending upwardly from the edge of the flat portion. The floating gate 117a has a first outer side adjacent to the active region and a second outer side adjacent to the device isolation layer 109. The sacrificial pattern 119a is formed in an empty region surrounded by the wall portion, in contact with the inner side of the floating gate 117a and the top surface of the flat portion of the floating gate 117a.

Due to the planarization of the sacrificial layer 119 and the gate layer 117, the floating gate 117a is isolated from an adjacent floating gate 117a. In a case where the width of the gate hole 113 is greater than the width of the active region, the distance between the facing second outer sides of the floating gate 117a may be formed greater than the width of the active region. As a result, the surface area of the floating gate 117a may be increased.

The planarization may be conducted by means of, for example a chemical mechanical polishing (CMP) or an etchback process.

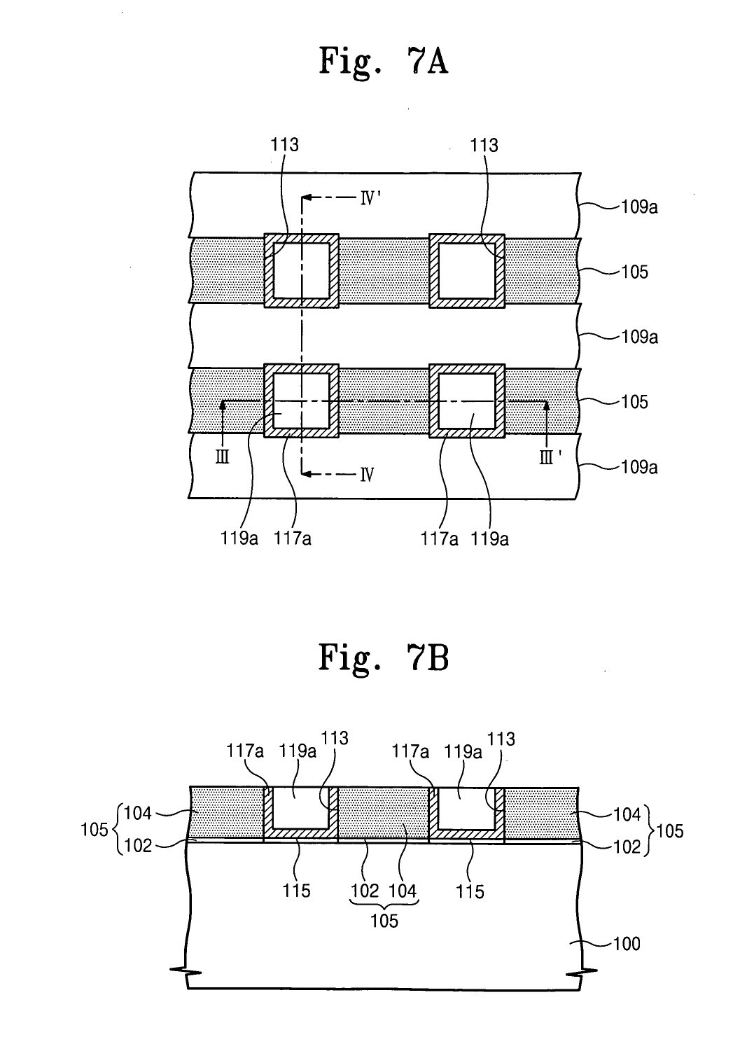

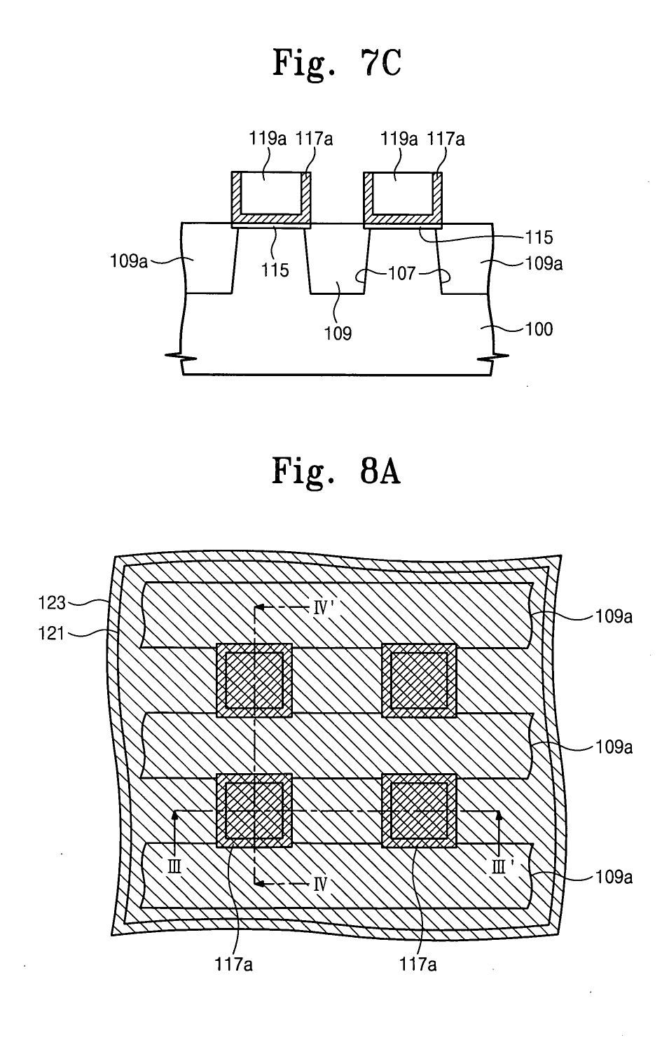

Referring to FIG. 7A, FIG. 7B, and FIG. 7C, the device isolation layer 109 is selectively etched to expose the second outer side of the floating gate 117a. The etching of the device isolation layer 109 may be performed by means of etchback process. A top surface of the etched device isolation layer 109 may be formed substantially level with a bottom surface of the flat portion of the floating gate 117a. Alternatively, a central portion of the top surface of the etched device isolation layer 109a may be formed lower than the bottom surface of the flat portion of the floating gate 117a. The etched device isolation layer 109a may cover a side of the tunnel insulation layer 115.

While the device isolation layer 109 is etched back, the sacrificial pattern 119a protects the inner side of the floating gate 117a and the top surface of the flat portion of the floating gate 117a from etch damage.

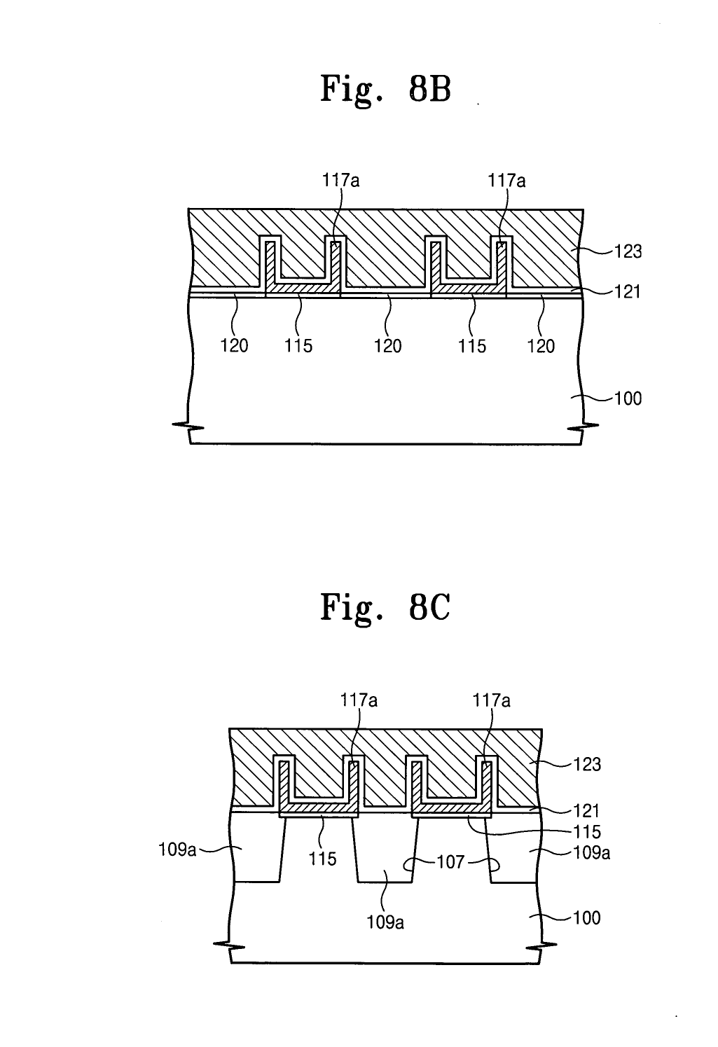

Referring to FIG. 8A, FIG. 8B, and FIG. 8C, the patterned hard mask pattern 105 is etched to expose the first outer side of the floating gate 117a. The patterned hard mask pattern 105 may be fully removed to expose the active region. Alternatively, the second layer 104 of the patterned hard mask pattern 105 may be removed while the first layer 102 thereof may remain. The etching of the patterned hard mask pattern 105 may be performed by means of wet etch and/or anisotropic etch process.

The sacrificial pattern 119a is removed to expose the inner side of the floating gate 117a and the top surface of the flat portion of the floating gate 117a. In a case where both the sacrificial pattern 119a and the second layer 104 of the patterned hard mask pattern are made of silicon nitride, the second layer 104 and the sacrificial pattern 119a may be removed at the same time. In other words, the inner side, the top surface of the flat portion, and the first outer side of the floating gate 117a may be exposed at the same time.

A buffer insulator 120 is formed on the active region formed at opposite sides adjacent to the floating gate 117a. The buffer insulator 120 may include the remaining first layer 102 of the patterned hard mask pattern 105. Alternatively, the buffer insulator 120 may be an insulator newly formed on the active region. The buffer insulator 120 may be made of, for example, silicon oxide.

A blocking insulator 121 is formed on an entire surface of the semiconductor substrate 100, covering a surface (the inner side, the first and second outer side, and the top surface of the flat portion) of the floating gate 117a. The blocking insulator 121 is made of an insulating material having a higher dielectric constant than the tunnel insulator 115. Thus, the blocking insulator 121 may be made of, for example, oxide-nitride-oxide (ONO) or insulative metal oxide (e.g., hafnium oxide or aluminum oxide).

A control gate conductive layer 123 is formed on the blocking insulator 121. As illustrated, a top surface of the control gate conductive layer 123 may be planarized to fill an empty region surrounded by the wall portion of the floating gate 117a. The control gate conductive layer 123 covers the inner side, the first and second outer sides, and the top surface of the flat portion of the floating gate 117a. The control gate conductive layer 123 may be made of at least one material selected from the group consisting of, for example, doped polysilicon, conductive metal nitride (e.g., titanium nitride or tantalum nitride), metal (e.g., tungsten or molybdenum), metal silicide (e.g., tungsten silicide or cobalt silicide), and combinations thereof.

A capping insulator may be formed on the control gate conductive layer 123.

The control gate conductive layer 123 may be patterned to form the control gate electrode 123a of the exemplary embodiment of the present invention illustrated in FIG. 1A, FIG. 1B, and FIG. 1C. As described above, the control gate electrode 123a is formed to cover the inner side, the top surface of the flat portion, and the second outer side of the floating gate 117a. Additionally, the opposite sides of the control gate electrode 123a are disposed on the blocking insulator 121 formed on a top surface of the wall portion of the floating gate 117a. When the control gate conductive layer 123 is patterned, the blocking insulator 121 may be used as an etch-stop layer. Using the control gate electrode 123a and the floating gate 117a as a mask, impurities are implanted to form the impurity-doped layer 125 illustrated in FIG. 1B. As a result, a non-volatile memory device according to the exemplary embodiment of the present invention illustrated in FIG. 1A, FIG. 1B, and FIG. 1C may be obtained.

Meanwhile, the control gate conductive layer 123 may be patterned to form the control gate electrode 123a′ illustrated in FIG. 2. As described above, the control gate electrode 123a′ is formed to cover the inner side, the top surface of the flat portion, and the second outer side of the floating gate 117a, as well as the first outer side of the floating gate 117a. In this case, the blocking insulator 121 may also be used as an etch-stop layer. Using the floating gate 117a and the control gate electrode 123a′ as a mask, impurities are implanted to form the impurity-doped layer 125 illustrated in FIG. 2. As a result, a non-volatile memory device according to the exemplary embodiment of the present invention illustrated in FIG. 2 may be obtained.

According to the above-described method of exemplary embodiments of the present invention, the floating gate 117a may be in the form of, for example, a channel or trough shape and includes a flat portion and a wall portion extending upwardly from the edge of the flat portion. The floating gate 117a is formed using the gate hole 113a formed by selectively patterning the hard mask pattern 105. Each of the control gate electrodes 123a and 123a′ is formed to cover an inner side, a top surface of the flat portion, and at least a part of an outer side of the floating gate 117a. Accordingly, an overlap area of each of the control gate electrodes 123a and 123a′ and the floating gate 117a increases and thus the capacitance therebetween also increases. Due to the increase of the overlap area and the capacitance, the coupling ratio is also raised, thereby resulting in a drop in the operating voltage of the non-volatile memory device and thus also a significant reduction in the power consumption of the device. Consequently, a highly integrated non-volatile memory device having lower power consumption is obtained.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A non-volatile memory device comprising:
a device isolation layer disposed on a semiconductor substrate to define an active region;
a floating gate disposed on the active region, the floating gate comprising a substantially flat portion and a wall portion extending upwardly from an edge of the substantially flat portion;
a tunnel insulator interposed between the floating gate and the active region;
a control gate electrode crossing over the active region and covering an inner side of the floating gate and at least a part of an outer side of the floating gate; and
a blocking insulator interposed between the control gate electrode and the floating gate.

2. The non-volatile memory device of claim 1, wherein the floating gate further comprises a first outer side adjacent to the active region and a second outer side adjacent to the device isolation layer, and the control gate electrode covers the second outer side.

3. The non-volatile memory device as recited in claim 2, wherein the control gate electrode comprises a side disposed on the blocking insulator disposed on a top surface of the wall portion.

4. The non-volatile memory device as recited in claim 3, further comprising:
an impurity-doped layer disposed in the active region formed at opposite sides adjacent to the control gate electrode and aligned with the first outer side of the floating gate.

5. The non-volatile memory device as recited in claim 2, wherein the control gate electrode extends to further cover the first outer side of the floating gate.

6. The non-volatile memory device as recited in claim 5, wherein the blocking insulator extends to be interposed between the active region and a portion covering the first outer side of the control gate electrode.

7. The non-volatile memory device as recited in claim 6, further comprising:
a buffer insulator interposed between an extending portion of the blocking insulator and the active region.

8. The non-volatile memory device as recited in claim 5, further comprising:
an impurity-doped layer disposed in the active region formed at opposite sides adjacent to the control gate electrode and aligned with the opposite sides of the control gate electrode.

9. The non-volatile memory device as recited in claim 2, wherein the floating gate further comprises a pair of second outer sides each being adjacent to the device isolation layer and disposed at opposite sides adjacent to the active region; and
wherein a distance between the pair of the second outer sides is greater than a width of the active region that is parallel with the distance between the pair of the second outer sides.

10. The non-volatile memory device as recited in claim 1, wherein the blocking insulator comprises an insulating material having a higher dielectric constant than the tunnel insulator.

11. A method of forming a non-volatile memory device, comprising:
forming a device isolation layer on a semiconductor substrate to define an active region;
forming a gate insulator on a predetermined region of the active region;
forming a floating gate on the gate insulator, the floating gate comprising a substantially flat portion and a wall portion extending upwardly from an edge of the substantially flat portion, wherein inner and outer sides of the floating gate are exposed;
forming a blocking insulator on substantially an entire surface of a semiconductor substrate including the floating gate; and
forming a control gate electrode on the blocking insulator to cross over the active region, the control gate electrode covering the inner side of the floating gate and at least a part of the outer side of the floating gate.

12. The method as recited in claim 11, further comprises forming the floating gate to include a first outer side adjacent to the active region and a second outer side adjacent to the device isolation layer, and the control gate electrode covers the second outer side of the floating gate.

13. The method as recited in claim 12, further comprising forming the control gate electrode to include a side disposed on the blocking insulator formed on a top surface of the wall portion.

14. The method as recited in claim 12, further comprising extending the control gate electrode to further cover the first outer side of the floating gate.

15. The method as recited in claim 11, wherein the forming of the device isolation layer and the floating gate comprises:
etching the semiconductor substrate using a hard mask pattern on the semiconductor substrate as a mask to form a trench;
forming the device isolation layer to fill the trench;
patterning the hard mask pattern to form a gate hole exposing a predetermined region of the active region;
forming a tunnel insulator on the exposed active region;
forming the floating gate in the gate hole; and
exposing the inner side and the outer side of the floating gate.

16. The method as recited in claim 15, wherein the forming of the floating gate in the gate hole comprises:
forming a gate layer on a semiconductor substrate including the gate hole and the tunnel insulator;
forming a sacrificial layer on the gate layer, the sacrificial layer having an etch selectivity with respect to the gate layer; and
planarizing the sacrificial layer and the gate layer, until the patterned hard mask pattern and the device isolation layer are exposed, to form the floating gate and a sacrificial pattern in the gate hole.

17. The method as recited in claim 16, wherein the exposing of the inner and outer sides of the floating gate comprises:
etching the device isolation layer to expose the outer side of the floating gate adjacent to the device isolation layer;
etching the patterned hard mask pattern to expose the outer side of the floating gate adjacent to the active region; and
removing the sacrificial pattern to expose the inner side of the floating gate.

18. The method as recited in claim 15, wherein the hard mask pattern comprises a first layer and a second layer; and
wherein forming the gate hole comprises:
patterning the second layer to expose a predetermined region of the first layer; and
etching the exposed first layer by means of isotropic wet etch to expose a predetermined region of the active region, wherein an upper portion of the device isolation layer is isotropically recessed by the isotropic wet etch.

19. The method as recited in claim 15, further comprising:
forming a buffer insulator between the blocking insulator and the active region formed at opposite sides adjacent to the floating gate.

20. The method as recited in claim 11, further comprising:
implanting impurity ions using the floating gate and the control gate electrode as a mask, to form an impurity-doped layer in the active region.

21. The non-volatile memory device as recited in claim 1, wherein the floating gate is the form of one of a channel or trough shape.

22. The method of claim 11, wherein the floating gate is in the form of one of a channel or trough shape.
